(19) United States
(12) Patent Application Publication
(10) Pub. No.: US 2012/0024357 A1
(43) Pub. Date: Feb. 2, 2012

(54) Laminated solar-cell module

(76) Inventor: Yao-Tung Chen, Taoyuan County (TW)

(21) Appl. No.: 12/805,463

(22) Filed: Aug. 2, 2010

(51) Int. Cl. H01L 31/0232

(52) U.S. Cl. 136/252

(57) ABSTRACT

A laminated solar-cell module includes a light collection unit, a light transmission unit, and a solar-cell unit. The solar-cell modules are laminated and connected in series or in parallel so as to increase the efficiency of photoelectric conversion. Multiple solar-cell units are connected to be a solar-cell array to include the efficiency of photoelectric conversion per unit area. The solar-cell array is used in houses to avoid from rains, wind and sun light and has longer term of use.

### BACKGROUND OF THE INVENTION

(1) Field of the Invention

The present invention relates to a solar-cell module, and more particularly, to a laminated solar-cell module.

(2) Description of the Prior Art

A conventional light guiding panel generally includes a reflector mounted to the panel and the light beams are introduced into the light guiding panel so that the light beams are repeatedly reflected between the reflector and the panel. Therefore, the light can be used and absorbed in a higher efficiency. When there are protrusions on the reflector, the light beam becomes a light plane which is collected by the diffusion lenses and prisms to increase the brightness of the light. The collected light is diffused from one side of the protection film and spread to the light zone.

There is a light guiding panel which allows the light to be reflected from two sides thereof. However, in the industry of solar cells, there lacks a way to combine the light guiding panel with two reflection sides, light collection member and other related parts, so that the solar cells are bulky and cannot be laminated and used on a limited area.

The present invention intends to provide a laminated solar-cell module which improves the shortcomings of the conventional solar-cells.

### SUMMARY OF THE INVENTION

The present invention relates to a laminated solar-cell module which comprises a light collection unit and at least one light transmission unit transmitting light collected by the light collection unit. A solar-cell unit has a light guiding member and at least one photoelectric conversion member. The light guiding member is connected to the at least one photoelectric conversion member. The light guiding member scatters the light collected by the light collection unit from the reflection surface to the receiving surface of the at least one photoelectric conversion member so as to transforming the light into electric energy. The light guiding member is a panel having a single reflection surface or two reflection surfaces. The light guiding member can also be a film having a single reflection surface or two reflection surfaces. The receiving surface of the at least one photoelectric conversion member is connected to the reflection surface of the light guiding member. A power transformer unit is connected to the solar-cell unit and stores electric energy transformed by the solar-cell unit. Multiple solar-cell units are connected to be a solar-cell array when needed.

The primary object of the present invention is to provide a laminated solar-cell module which includes a light collection unit, a light transmission unit, and a solar-cell unit. The solar-cell modules are laminated and connected in series or in parallel so as to increase the efficiency of photoelectric conversion. Multiple solar-cell units are connected to be a solar-cell array to include the efficiency of photoelectric conversion per unit area. The solar-cell array is used in houses to avoid from rains, wind and sun light and has longer term of use.

The present invention will become more obvious from the following description when taken in connection with the accompanying drawings which show, for purposes of illustration only, a preferred embodiment in accordance with the present invention.

### BRIEF DESCRIPTION OF THE DRAWINGS

FIG. 1 shows the laminated solar-cell module of the present invention, and

FIG. 2 shows that laminated solar-cell module of the present invention is used in a house, and

FIG. 3 shows another use of the laminated solar-cell module of the present invention.

### DETAILED DESCRIPTION OF THE PREFERRED EMBODIMENT

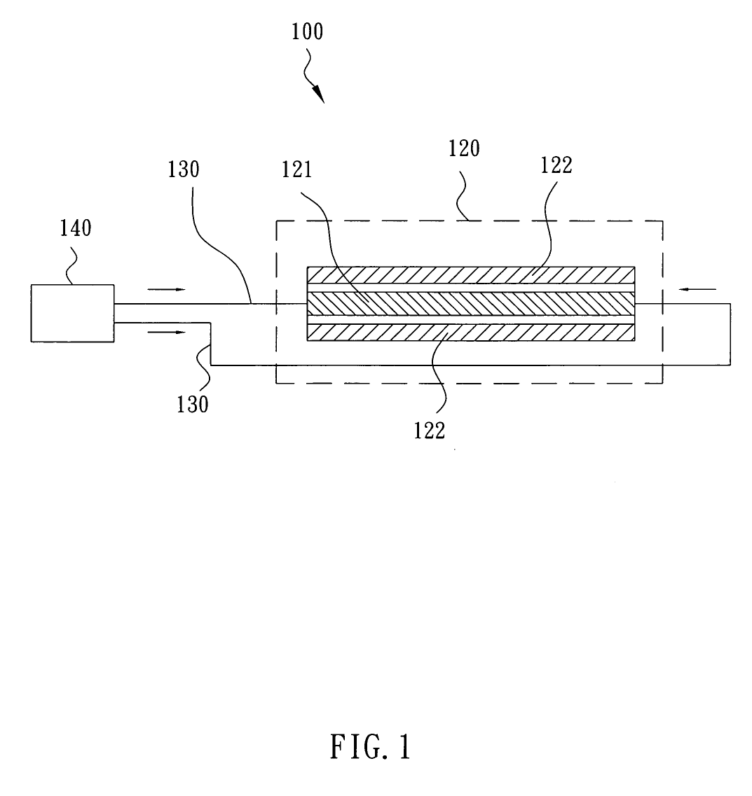

Referring to FIG. 1, the laminated solar-cell module 100 of the present invention comprises at least one solar-cell unit 120, a light transmission unit 130 and a light collection unit 140, wherein the light collection unit 140 is a light collection member or a light collection panel. The at least one solar-cell unit 120 includes a light guiding member 121 and at least one photoelectric conversion member 122. The light guiding member 121 can be a panel or a film having a single reflection surface or two reflection surfaces. The light guiding member 121 scatters the light collected by the light collection unit 140 from the reflection surface to the receiving surface of the at least one photoelectric conversion member 122 so as to transforming the light into electric energy. The receiving surface of the at least one photoelectric conversion member 122 is connected to the reflection surface of the light guiding member 121 having two reflection surfaces. The solar-cell units 120 can be combined to be a solar-cell array 120A as needed. The at least one light transmission unit 130 is an optical fiber or a light guidance tube. The at least one light transmission unit 130 has a first end connected to the light collection unit 140 and a second end of the at least one light transmission unit 130 is connected to the light guiding member 121 so as to transmit the light collected by the light collection unit 140 and to reflect the light from at least one reflection surface of the light guiding member 121.

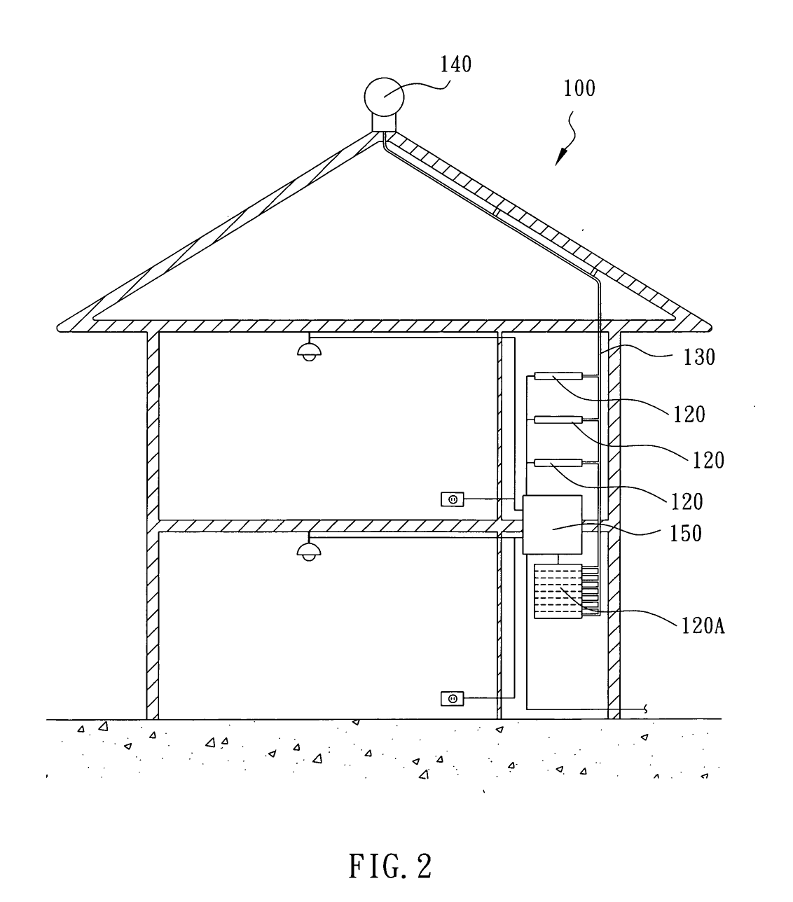

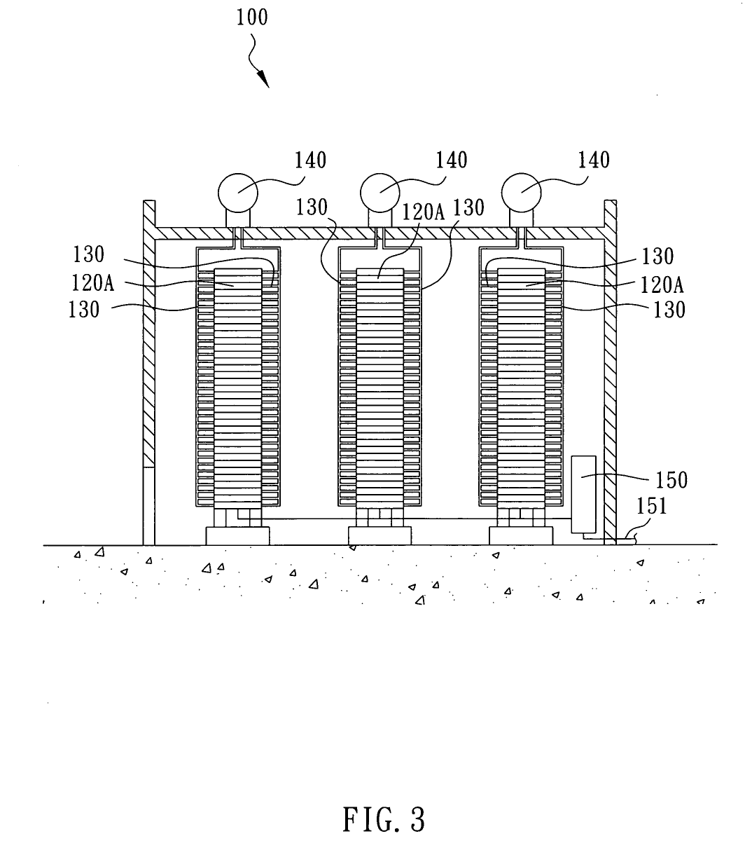

A preferable embodiment of the present invention is shown in FIG. 2 and the laminated solar-cell module 100 is installed in a house and includes multiple solar-cell units 120. A power transformer unit 150 is connected to the solar-cell unit 120 and stores electric energy transformed by the solar-cell unit 120. The power transformer unit 150 is connected to appliances and provides the electric power to the appliances. The solar-cell units 120 can be installed individually or combined to form a solar-cell array 120A as needed. As shown in FIG. 3, the laminated solar-cell module 100 is installed in a house and includes multiple solar-cell arrays 120A. The transformed electric energy is transmitted to and stored in the power transformer unit 150. The power transformer unit 150 includes an output line 151 which delivers the electric energy to a transformer which dispenses the electric energy as needed.

While we have shown and described the embodiment in accordance with the present invention, it should be clear to those skilled in the art that further embodiments may be made without departing from the scope of the present invention.

What is claimed is:

1. A laminated solar-cell module comprising:
a light collection unit;
at least one light transmission unit transmitting light collected by the light collection unit;
at least one solar-cell unit having a light guiding member and at least one photoelectric conversion member, the light guiding member connected to the at least one photoelectric conversion member, the light guiding member scattering the light collected by the light collection unit from the reflection surface to the receiving surface of the at least one photoelectric conversion member so as to transforming the light into electric energy.

2. The module as claimed in claim 1, wherein the at least one light transmission unit has a first end connected to the light collection unit and a second end of the at least one light transmission unit is connected to the light guiding member so as to transmit the light collected by the light collection unit and to reflect the light from at least one reflection surface of the light guiding member.

3. The module as claimed in claim 1, wherein the light guiding member is a panel having a single reflection surface or two reflection surfaces.

4. The module as claimed in claim 1, wherein the light guiding member is a film having a single reflection surface or two reflection surfaces.

5. The module as claimed in claim 1, wherein the receiving surface of the at least one photoelectric conversion member is connected to the reflection surface of the light guiding member.

6. The module as claimed in claim 1, wherein the at least one light transmission unit is an optical fiber or a light guidance tube.

7. The module as claimed in claim 1, wherein the light collection unit is a light collection member or a light collection panel.

8. The module as claimed in claim 1, wherein the solar-cell units are combined to be a solar-cell array.

9. The module as claimed in claim 1, wherein a power transformer unit is connected to the solar-cell unit and stores electric energy transformed by the solar-cell unit.

10. The module as claimed in claim 9, wherein the power transformer unit includes an output line.
